(19) United States
(12) Patent Application Publication
(10) Pub. No.: US 2026/0269336 A1
(43) Pub. Date: Sep. 10, 2026

(54) WIRELESS BATTERY MANAGEMENT SYSTEM BASED ON CELL MONITORING UNIT (CMU) WITH WIRELESS COMMUNICATION PRIMARY FUNCTION AND OPERATION METHOD THEREFOR

(71) Applicants: HYUNDAI MOTOR COMPANY, SEOUL (KR); KIA CORPORATION, SEOUL (KR)

(72) Inventors: Jun Baek, Hwaseong-si (KR); Jonghu Yoon, Hwaseong-si (KR); Naeun Song, Hwaseong-si (KR)

(73) Assignees: HYUNDAI MOTOR COMPANY, SEOUL (KR); KIA CORPORATION, SEOUL (KR)

(21) Appl. No.: 19/275,170

(22) Filed: Jul. 21, 2025

(30) Foreign Application Priority Data
Mar. 10, 2025 (KR) 10-2025-0030618

(51) Int. Cl. H01M 10/42; B60L 58/18; H01M 10/48

(52) U.S. Cl. CPC H01M 10/425; B60L 58/18; H01M 10/4285; H01M 10/482; H01M 2010/4271; H01M 2010/4278

(57) ABSTRACT

A wireless battery management system may include a plurality of CMUs, and a battery management unit (BMU) implemented externally to the battery system, where a primary CMU among the plurality of CMUs may be configured to receive cell status information measured by the plurality of CMUs via wireless communication and transmit the received cell status information to the BMU.

### CROSS REFERENCE TO RELATED APPLICATIONS

This present application claims the benefit of priority to Korean Patent Application No. 10-2025-0030618, filed on Mar. 10, 2025, in the Korean Intellectual Property Office, the entire disclosure of which is incorporated herein by reference.

### BACKGROUND

### a. Technical Field

The present disclosure relates to a battery management system and an operation method therefor. More specifically, the present disclosure relates to a wireless battery management system that removes a battery management unit (BMU) of a battery management system (BMS) from inside a battery system and implements BMS wireless communication using only cell monitoring units (CMUs), and an operation method therefor.

### b. Description of the Related Art

A key competitive feature of eco-friendly vehicles such as electric vehicles (EVs), hybrid electric vehicles (HEVs), and plug-in hybrid electric vehicles (PHEVs) is their driving range, and for this purpose, a sufficient absolute space within the battery system to accommodate as many batteries as possible is required.

A battery management system (BMS) is a system that controls and manages the charging and discharging of such a battery system, and a BMS is composed of one or more cell monitoring units (CMUs) that monitor multiple batteries, and a battery management unit (BMU) that manages the CMUs.

Recently, to secure space for battery installation, communication between the BMU (primary) and the CMUs (secondary) in the BMS has been implemented using wireless communication rather than traditional wire-based communication. By eliminating communication wires, there is a trend toward securing absolute space and improving energy density.

In existing technology, the BMU (primary) in the BMS performs the role of a wireless primary that controls wireless communication among all CMUs in the battery system and thus is mounted inside the battery system.

However, in the existing technology, the BMU is mounted/implemented in an independent space of a particular area or larger within the battery system, in consideration of factors such as after-service (A/S) accessibility, electromagnetic immunity performance, insulation clearance distance, and the like, which imposes limitations in terms of securing space for battery installation in the battery system and in terms of energy density.

The matters described in this Background section are only for the enhancement of understanding of the background of the disclosure and should not be taken as acknowledgment that they correspond to prior art already known to those skilled in the art.

### SUMMARY

The following summary presents a simplified summary of certain features. The summary is not an extensive overview and is not intended to identify key or critical elements.

The present disclosure is directed to providing a wireless battery management system based on a cell monitoring unit (CMU) with a wireless communication primary function, which removes a battery management unit (BMU) of a battery management system (BMS) from inside a battery system and implements BMS wireless communication using only the CMU, and an operation method therefor.

Aspects of the present disclosure are not limited to those mentioned above, and other aspects and advantages not mentioned above will be understood from the following description and become more apparent from the exemplary embodiments. Moreover, aspects of the present disclosure may be realized by the means and combinations thereof indicated in claims.

According to one aspect of the present disclosure, a wireless battery management system based on a cell monitoring unit (CMU) may include a plurality of CMUs connected to respective battery modules constituting a battery system and configured to measure the status of the battery modules, and a battery management unit (BMU) implemented externally to the battery system, wherein a primary CMU having a wireless communication primary function among the plurality of CMUs may be configured to receive, via wireless communication, cell status information measured by the plurality of CMUs, and transmit the received cell status information to the BMU.

The primary CMU may include two or more wireless interface units for wireless communication and may diagnose a wireless communication status for the two or more wireless interface units and reset the two or more wireless interface units based on an error being diagnosed.

The BMU may be configured to determine whether the cell status information for all battery modules within the battery system is normally received from the primary CMU.

The primary CMU may be configured to diagnose the wireless communication status based on the cell status information for all battery modules not being normally received by the BMU.

The primary CMU may be configured to diagnose the wireless communication status by diagnosing, based on a wireless data packet success rate and a number of retransmissions received from the plurality of CMUs via a first wireless interface unit among the two or more wireless interface units, the wireless communication status of the first wireless interface unit, resetting the first wireless interface unit based on a reception error being diagnosed for the first wireless interface unit, and resetting a second wireless interface unit among the two or more wireless interface units based on a reception error not being diagnosed for the first wireless interface unit.

A communication structure between the BMU and the primary CMU may be configured such that each wireless interface unit of the primary CMU is connected to the BMU via wired communication.

The primary CMU may include a module measurement function unit configured to measure the status of a battery module to which the primary CMU is connected, and a wireless communication primary function unit configured to receive, via wireless communication, cell status information measured respectively by CMUs other than the primary CMU among the plurality of CMUs and by the module measurement function unit, and transmit the received cell status information to the BMU.

According to another aspect of the present disclosure, a primary cell monitoring unit (CMU) may include a module measurement function unit configured to measure the status of a battery module to which the primary CMU is connected within a battery system, and a wireless communication primary function unit configured to receive, via wireless communication, cell status information measured by other CMUs connected to other battery modules in the battery system and cell status information measured by the module measurement function unit, and to transmit the received cell status information to a battery management unit (BMU) implemented externally to the battery system.

The wireless communication primary function unit may include two or more wireless interface units for wireless communication, and may be configured to diagnose a wireless communication status for the two or more wireless interface units and reset the two or more wireless interface units based on an error being diagnosed.

The wireless communication primary function unit may be configured to use a power source different from the power source used by the module measurement function unit.

The wireless communication primary function unit may be configured to receive and use a vehicle power source different from a power source used by the module measurement function unit.

The module measurement function unit may be in a high voltage (HV) domain, and the wireless communication primary function unit may be in a low voltage (LV) domain. The module measurement function unit in the high voltage (HV) domain and the wireless communication primary function unit in the low voltage (LV) domain may be designed to be electrically isolated from one another within the primary CMU.

According to still another aspect of the present disclosure, an operation method for a wireless battery management system based on a cell monitoring unit (CMU) may include, by a plurality of CMUs connected to respective battery modules constituting a battery system, measuring a status of the battery modules, by a primary CMU having a wireless communication primary function receiving cell status information measured by the plurality of CMUs via wireless communication, and by the primary CMU, transmitting the cell status information received via wireless communication to a battery management unit (BMS) implemented externally to the battery system.

The method may further include, by the BMU, determining whether cell status information for all battery modules within the battery system is normally received from the primary CMU, and based on the cell status information for all battery modules not being normally received by the BMU from the primary CMU, diagnosing a wireless communication status for two or more wireless interface units for wireless communication.

The diagnosing a wireless communication status may include diagnosing, based on a wireless data packet success rate and a number of retransmissions received from the plurality of CMUs via a first wireless interface unit among the two or more wireless interface units, the wireless communication status of the first wireless interface unit, resetting the first wireless interface unit based on a reception error being diagnosed for the first wireless interface unit, and resetting a second wireless interface unit among the two or more wireless interface units based on a reception error not being diagnosed for the first wireless interface unit.

A communication structure between the BMU and the primary CMU may be configured such that each wireless interface unit of the primary CMU is connected to the BMU via wired communication.

According to embodiments of the present disclosure, by removing the BMU from the battery system and implementing BMS wireless communication using only CMUs, the space used for installing the BMU in conventional battery systems may be used as a space for additional battery installation, thereby securing energy density, and furthermore, a maintenance access panel for BMU servicing at the bottom of the battery system may be removed, thereby securing battery stability.

Furthermore, according to embodiments of the present disclosure, by implementing a primary CMU with a wireless communication primary function at a location favorable for optimization of the structure and performance of wireless communication in the battery system, wireless communication performance may be improved and cell monitoring performance may be enhanced through the freedom to position the primary CMU optimally.

### BRIEF DESCRIPTION OF THE FIGURES

The foregoing and other aspects, as well as the following detailed description of the embodiments, should be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a diagram illustrating a BMS wireless communication structure according to the prior art, in which a BMU and CMUs of a BMS are mounted inside a battery system.

FIG. 2 is a diagram illustrating a structure according to the present disclosure that removes (implements externally) a BMU from the battery system, and implements BMS wireless communication using only CMUs in a battery system.

FIG. 3 is a configuration diagram illustrating a wireless battery management system based on a CMU with a wireless communication primary function according to an embodiment of the present disclosure.

FIG. 4 is a detailed diagram illustrating a configuration of a CMU with a wireless communication primary function according to an embodiment of the present disclosure.

FIGS. 5 and 6 are flowcharts illustrating an operation method of a wireless battery management system based on a CMU with a wireless communication primary function according to an embodiment of the present disclosure.

### DETAILED DESCRIPTION

Embodiments of the present disclosure will be described in greater detail with reference to the accompanying drawings, and throughout the accompanying drawings, the same reference numerals are used to designate the same or similar components and redundant descriptions thereof are omitted. As used herein, the terms "module" and "unit" used to refer to components are used interchangeably for convenience of explanation, and thus, the terms per se should not be considered as having different meanings or functions. In relation to describing the present disclosure, when the detailed description of the relevant known technology is determined to obscure the gist of the present disclosure unnecessarily, detailed description thereof may be omitted. Furthermore, it should be understood that the appended drawings are intended only to help understand embodiments disclosed in the present disclosure and do not limit the technical principles and scope of the present disclosure. Rather, it should be understood that the appended drawings include all of the modifications, equivalents or substitutes described by the technical principles and belonging to the technical scope of the present disclosure.

Although the terms first, second, third, and the like may be used herein to describe various elements, components, regions, layers, and/or sections, these elements, components, regions, layers, and/or sections should not be limited by these terms. These terms are only used to distinguish one element from another.

When an element or layer is referred to as being "on," "engaged to," "connected to," or "coupled to" another element or layer, it may be directly on, engaged, connected, or coupled to the other element or layer, or intervening elements or layers may be present. In contrast, when an element is referred to as being "directly on," "directly engaged to," "directly connected to," or "directly coupled to" another element or layer, there may be no intervening elements or layers present.

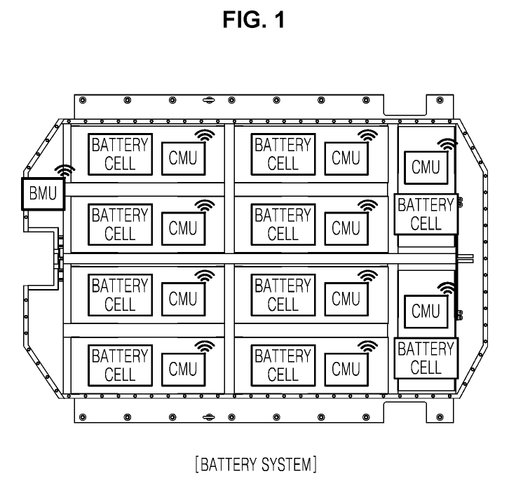

Hereinafter, a wireless battery management system based on a CMU with a wireless communication primary function and an operation method therefor, according to the present disclosure, will be described in detail with reference to FIGS. 1-6.

Before describing the present disclosure, a BMS wireless communication structure according to the prior art will be explained with reference to FIG. 1.

FIG. 1 is a diagram illustrating a BMS wireless communication structure according to the prior art, in which a BMU and CMUs of a BMS are mounted inside a battery system.

Referring to FIG. 1, in the prior art, a wireless communication battery management system (BMS) in a battery system comprises a battery management unit (BMU) that acts as a wireless manager overseeing the overall wireless communication, and cell monitoring units (CMUs) that act as wireless nodes measuring battery cell voltage/temperature, cell balancing, and the like.

As can be seen from FIG. 1, according to the prior art, in the BMS, the BMU, which acts as the wireless manager that controls wireless communication between all CMUs in the battery system, is mounted inside the battery system.

The status of the battery cells in the battery system, such as voltage/temperature, cell balancing, and the like, is measured by the respective CMUs mounted/connected to each battery module, and this measured cell status information is transmitted by the CMUs to the BMU via wireless communication.

Further, in the prior art, a wireless communication status in the battery system (e.g., reception strength, number of wireless communication failures, and the like) is determined by the BMU, all wireless data transmission and reception in the battery system is managed by the BMU, and all wireless nodes (CMUs) transmit and receive wireless data through the wireless manager (BMU).

However, according to the prior art, the BMU is mounted/implemented in an independent space of a certain area or larger within the battery system considering ease of maintenance, electromagnetic immunity performance, insulation clearance distance, and the like, which presents a limitation on securing space for battery mounting and energy density in the battery system.

In the present disclosure, in order to address this limitation, a new BMS wireless communication structure is proposed that implements BMS wireless communication using only CMUs by removing the BMU of the BMS from inside the battery system.

In the present disclosure, a new BMS wireless communication structure based on a CMU with a wireless communication primary function (referred to as a primary CMU) is proposed. In this structure, the circuitry and wireless logic for the wireless Manager role, typically performed by a BMU, are implemented in a primary CMU.

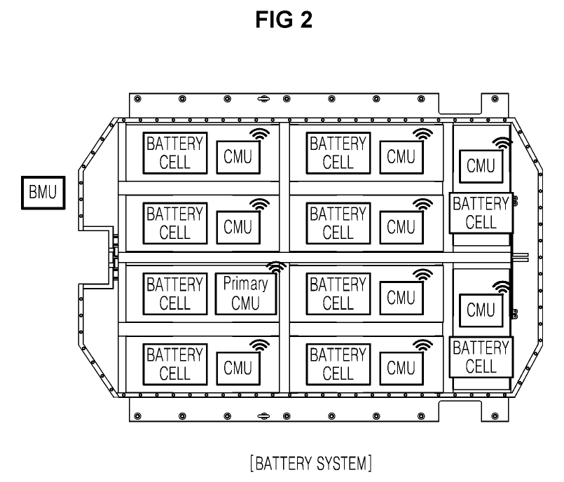

Hereinafter, the BMS wireless communication structure of the present disclosure will be explained with reference to FIG. 2.

FIG. 2 is a diagram illustrating a structure according to the present disclosure that removes (implements externally) a BMU from the battery system, and implements BMS wireless communication using only CMUs in a battery system.

As shown in FIG. 2, according to the present disclosure, the BMU is implemented externally to the battery system, and the circuit and wireless logic for the wireless manager role that a BMU typically performs are integrated/implemented in at least one of the plurality of CMUs within the battery system. Hereinafter, a CMU in which the circuit and wireless logic for the wireless manager role typically performed by a BMU are integrated/implemented, i.e., a CMU equipped with a wireless communication primary function, will be referred to as a “primary CMU.”

FIG. 2 shows an example of implementing one primary CMU in the battery system. According to embodiments of the present disclosure, the primary CMU may be implemented at the position of any CMU among the plurality of CMUs in the battery system.

In this way, by proposing a wireless BMS based on a primary CMU that removes the BMU of the BMS from inside the battery system and implements at least one of the CMUs as a primary CMU, battery stability and energy density may be secured through the removal of the BMU from the battery system, the removal of a maintenance access panel for BMU servicing, and the installation of additional battery cells.

However, since the wireless manager role typically performed by a BMU is integrated/implemented in a primary CMU, the current consumption of the primary CMU may increase compared to the remaining CMUs (hereinafter, “secondary CMUs”). This may lead to a capacity deviation between battery modules, which can in turn directly impact the drivable range.

To address this in more detail, embodiments of the present disclosure propose a wireless BMS based on a primary CMU as described above, and specifically proposes a communication circuit and logic in the primary CMU to prevent current consumption deviation between the primary CMU and the secondary CMUs and to stably deliver cell status information in the battery system to an external BMU.

Hereinafter, a wireless BMS based on a primary CMU and an operation method therefor, according to embodiments of the present disclosure, for implementing the new BMS wireless communication structure proposed in the present disclosure as described above, will be described.

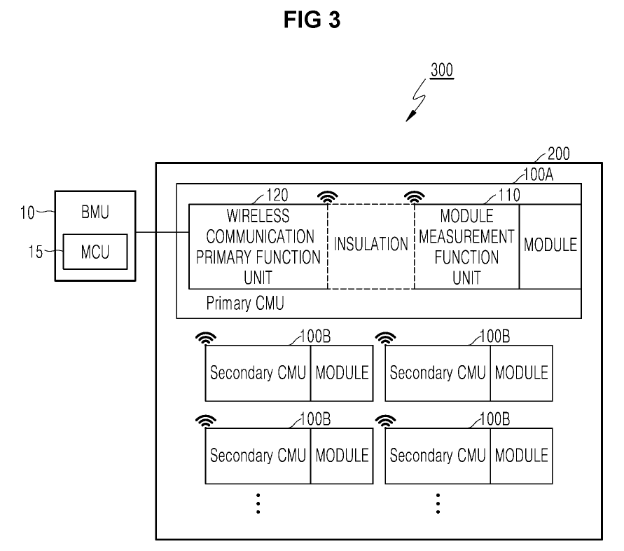

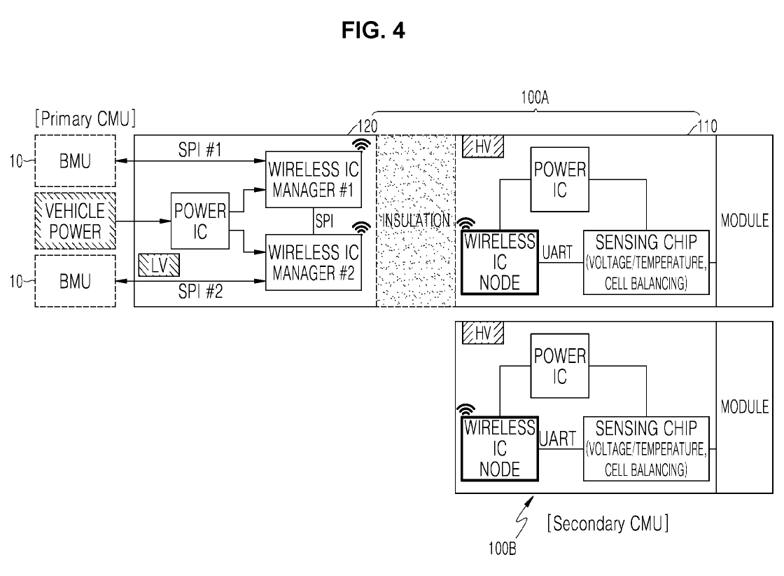

FIG. 3 is a configuration diagram illustrating a wireless BMS (300) based on a CMU with a wireless communication primary function (hereinafter, primary CMU) according to an embodiment of the present disclosure. FIG. 4 is a detailed diagram illustrating the configuration of the primary CMU according to an embodiment of the present disclosure.

Referring to FIG. 3, the wireless BMS (300) based on a primary CMU according to an embodiment of the present disclosure may comprise a plurality of CMUs (100A, 100B) connected to respective battery modules constituting a battery system (200) to measure the status of the battery modules, and a BMU (10) implemented externally to the battery system (200).

A primary CMU (100A) among the plurality of CMUs (100A, 100B) may receive cell status information measured by the plurality of CMUs (100A, 100B) via wireless communication, and transmit the received cell status information to the BMU (10).

The primary CMU (100A) may be a CMU with a wireless communication primary function among the plurality of CMUs (100A, 100B). Further, for convenience of explanation, the CMUs (100B) other than the primary CMU (100A) among the plurality of CMUs (100A, 100B) will be referred to as secondary CMUs (100B).

Each secondary CMU (100B) may measure the status (e.g., voltage/temperature, cell balancing, and the like) of the battery cells included in the battery module to which it is connected/directly connected to generate cell status information, and transmit the cell status information to the primary CMU (100A), which performs the wireless manager role typically performed by a BMU within the battery system (200).

The BMU (10) may be implemented externally to the battery system (200), and as an example, may be implemented in an integrated power electronics module (IPEM) external to the battery system (200) within the vehicle.

The BMU (10) may be configured without including the circuit and wireless logic for the wireless manager role typically performed by a BMU, and may instead be composed of a determination logic (e.g., an MCU (15)) that determines whether there is a status abnormality of the battery modules in the battery system (200) based on the cell status information.

Accordingly, the BMU (10) may receive cell status information about the battery system (200) from the primary CMU (100A), and based on the received cell status information, determine whether there is a status abnormality of the battery modules in the battery system (200) and perform follow-up operations according to the determination, for example, performing subsequent cell monitoring operations in the battery system.

The primary CMU (100A) may perform the inherent function of a CMU of measuring the status of the battery cells included in the battery module to which it is connected/directly connected (e.g., measuring battery cell voltage/temperature, cell balancing, and the like), while simultaneously performing the wireless manager role that is typically performed by a BMU.

To this end, the primary CMU (100A) may have a structure that includes a module measurement function unit (110) configured to measure the status of the battery module to which the primary CMU (100A) itself is connected/directly connected (the inherent function of a CMU), and a wireless communication primary function unit (120) configured to receive the cell status information measured respectively by each secondary CMU (100B) and by the module measurement function unit (110) via wireless communication, and transmit the received cell status information to the BMU (10) (the wireless manager role that is typically performed by a BMU).

That is, the primary CMU (100A) includes the wireless communication primary function unit (120) to perform the wireless manager role that is typically performed by a BMU.

The wireless communication status in the battery system (200) (e.g., reception strength/number of wireless communication failures, and the like) may be determined by the primary CMU (100A).

All wireless data transmission and reception in the battery system (200) may be managed by a wireless IC manager (see FIG. 4) in the primary CMU (100A). To prevent complete failure of cell monitoring in the battery system due to a single wireless IC failure, the wireless IC manager may be implemented in a dual redundant configuration (see FIG. 4).

The primary CMU (100A) may configure its power based on both a module-based high voltage (HV) domain for measuring battery cell voltage/temperature, cell balancing, and the like, and a low voltage (LV) domain to prevent current consumption deviation between the primary CMU and the secondary CMUs (100B). The high voltage (HV) domain and the low voltage (LV) domain may be designed to be electrically isolated from one another.

Accordingly, in the primary CMU (100A), the wireless communication primary function unit (120) on the low voltage (LV) side performs the wireless manager role that is typically performed by a BMU, and the module measurement function unit (110) on the high voltage (HV) side performs the inherent functions of the CMU (measuring battery cell voltage/temperature, cell balancing, and the like, wireless transmission, and the like).

FIG. 4 illustrates the configuration of the primary CMU according to an embodiment of the present disclosure in more detail, and also illustrates the internal configuration of the secondary CMU (100B) to aid the explanation.

The secondary CMU (100B) has the same configuration as a conventional CMU, and may utilize power from a power IC and include a sensing chip that measures the status of the battery module (internal battery cells) (e.g., voltage/temperature, cell balancing, and the like.), and a wireless IC node that wirelessly transmits the measured cell status information.

Referring to FIG. 4, the primary CMU (100A) according to an embodiment of the present disclosure may comprise a module measurement function unit (110) configured to measure the status of the battery module to which the primary CMU (100A) is connected in the battery system (200), and a wireless communication primary function unit (120) configured to receive, via wireless communication, cell status information measured by secondary CMUs (100B) connected to other battery modules in the battery system (200) and cell status information measured by the module measurement function unit (110), and transmit the cell status information to the BMU (10) implemented externally to the battery system (200).

The module measurement function unit (110) may have the same configuration as a conventional CMU, and may utilize power from a module-based power IC and include a sensing chip that measures the status of the battery module (internal battery cells) (e.g., voltage/temperature, cell balancing, and the like), and a wireless IC node that wirelessly transmits the measured cell status information.

The wireless communication primary function unit (120) within the primary CMU (100A) is implemented to use a power source different from the one used by the module measurement function unit (110), in order to prevent current consumption deviation between the primary CMU (100A) and secondary CMUs (100B).

Preferably, the wireless communication primary function unit (120) may be implemented to receive and use vehicle power in the low voltage (LV) domain, which differs from the power used by the module measurement function unit (110) in the module-based high voltage (HV) domain.

That is, the wireless communication primary function unit (120) may use a power IC based on vehicle power, and has a configuration that includes a wireless interface unit for wireless communication inside the battery system (200).

Also, referring to FIG. 4, in the primary CMU (100A), the module measurement function unit (110) in the high voltage (HV) domain and the wireless communication primary function unit (120) in the low voltage (LV) domain may be designed to be electrically isolated from one another.

In more detail, the wireless communication primary function unit (120) may be a configuration for preventing complete failure of cell monitoring in the battery system due to a single wireless interface unit failure, and therefore may include two or more wireless interface units.

These wireless interface units may be implemented as wireless ICs (wireless integrated circuits) or the like, and as shown in FIG. 4 may be represented as wireless IC manager #1 and wireless IC manager #2.

By implementing the wireless interface units, i.e., the wireless IC managers, in the primary CMU (100A) in a dual redundant configuration in this way, when an abnormality occurs in one of the wireless IC managers #1, #2, the other one replaces it to perform normal wireless communication, thereby preventing wireless communication transmission failure and increasing communication reliability.

The communication structure between the BMU (10) and the primary CMU (100A) may be designed as a structure in which the BMU (10) and each wireless IC manager #1, #2 in the primary CMU (100A) are connected by wired communication (e.g., a serial peripheral interface (SPI)).

The wireless IC managers #1, #2 in the primary CMU (100A) may receive cell status information for all battery modules in the battery system (200) via wireless communication, which includes receiving cell status information measured in the high voltage (HV) domain in the same primary CMU (100A).

The wireless IC managers #1, #2 in the primary CMU (100A) may transmit the cell status information received via wireless communication to the BMU (10) external to the battery system (200) through wired communication (e.g., SPI #1, #2).

Meanwhile, as described above, in the present disclosure, to prevent current consumption deviation between the primary CMU (100A) and secondary CMUs (100B) that would result from increased current in the primary CMU (100A) due to the addition of the wireless communication primary function unit (120), the system may implement a power architecture that utilizes vehicle power and an electrical insulation design.

With this arrangement, the measurement function in the HV domain within the primary CMU (100A) may be performed entirely by the sensing chip in the HV domain, while the function of the wireless manager role may be performed entirely in the LV domain using vehicle power. As a result, the current consumed from the module by the primary CMU (100A) is no different from that of the secondary CMU (100B), thus preventing capacity deviation between modules where the primary CMU (100A) and secondary CMUs (100B) are installed.

Hereinafter, an operation method of a wireless BMS based on a primary CMU according to an embodiment of the present disclosure, for implementing the new BMS wireless communication structure proposed in the present disclosure as described above, will be described.

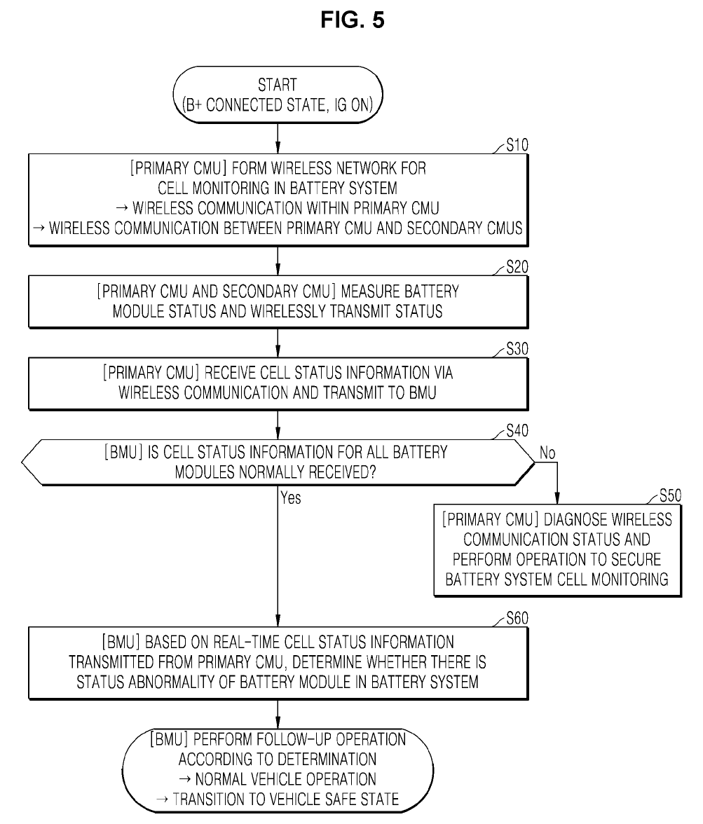

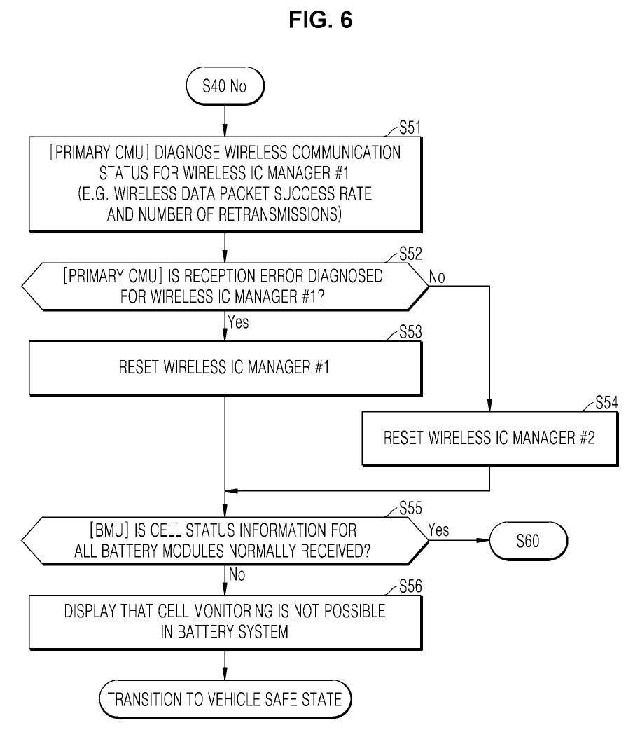

FIGS. 5 and 6 are flowcharts illustrating an operation method of the wireless BMS based on a primary CMU according to an embodiment of the present disclosure. In the following description, for convenience of explanation, reference numbers from FIGS. 3-4 will be mentioned.

Referring to FIG. 5, according to the operation method of the wireless BMS based on a primary CMU according to an embodiment of the present disclosure, when an ignition device (IG) is turned on in a state in which the battery system (200) is connected to constant power (B+), at step S10, a wireless network may be formed for cell monitoring in the battery system (200).

For example, the wireless IC managers #1, #2 in the primary CMU (100A) may form a wireless network with the wireless IC node of the module measurement function unit (110) in the primary CMU (100A) to establish wireless communication within the primary CMU (100A).

Additionally, the wireless IC managers #1, #2 in the primary CMU (100A) may form a wireless network with the wireless IC nodes in each secondary CMU (100B), establishing wireless communication between the primary CMU (100A) and the secondary CMUs (100B).

The wireless communication connection within the primary CMU (100A) and the wireless communication connection between the primary CMU (100A) and the secondary CMUs (100B) performed at step S10 may be carried out in parallel.

Furthermore, at step S20, the module measurement function unit (110) in the primary CMU (100A) and each secondary CMU (100B) may measure the status (e.g., voltage/temperature, cell balancing, and the like.) of the battery module to which they are connected/directly connected, and wirelessly transmit the status to the primary CMU (100A).

At step S30, the wireless IC managers #1, #2 in the primary CMU (100A) may transmit the cell status information received via wireless communication to the BMU (10) through wired communication.

The BMU (10) may determine whether cell status information for all battery modules in the battery system (200) is normally received from the Primary CMU (100A).

Based on the cell status information for all battery modules in the battery system (200) not being normally received by the BMU (10) (“No” in step s40), at step S50, the primary CMU (100A) may diagnose the wireless communication status for each wireless IC manager #1, #2, and perform operations to secure cell monitoring in the battery system (200) (explained in FIG. 6 below).

Based on the cell status information for all battery modules in the battery system (200) being normally received by the BMU (10) at step S40 (“Yes” in step S40), at step S60, the BMU (10) may determine whether there is a status abnormality of the battery modules in the battery system (200) based on real-time cell status information transmitted from the primary CMU (100A).

The BMU (10) may perform follow-up operations according to the determination at step S60, for example, performing various operations for normal vehicle driving when the status is determined to be normal, and performing various operations to transition the vehicle to a safe state when the status is determined to be abnormal.

Referring to FIG. 6, step S50 performed in the operation method of the wireless BMS based on a primary CMU of the present disclosure will be explained in more detail.

According to the operation method of the wireless BMS based on a primary CMU according to the present disclosure, based on the cell status information for all battery modules in the battery system (200) not being normally received by the BMU (10) at step S40 (“No” in step S40), at steps S51-52, the primary CMU (100A) may perform diagnosis of the wireless communication status for the wireless IC managers #1, #2.

In detail, at step S51, the primary CMU (100A) may perform a process of diagnosing the wireless communication status of the wireless IC manager #1 based on a wireless data packet success rate and a number of retransmissions received from a plurality of CMUs (secondary CMUs (100B) and the module measurement function unit (110) in the primary CMU (100A)) through one of the wireless IC managers #1, #2, for example, the wireless IC manager #1.

Based on a reception error being diagnosed for the wireless IC Manager #1 as a result of the diagnosis at step S51 (“Yes” in step S52), the primary CMU (100A) may perform a process of resetting the wireless IC manager #1 at step S53.

Based on a reception error not being diagnosed for the wireless IC manager #1 as a result of the diagnosis at step S51 (“No” in step S52), the primary CMU (100A) may perform a process of resetting the other wireless IC manager #2 among the wireless IC managers #1, #2 at step S54.

At step S55, the BMU (10) may determine whether cell status information for all battery modules in the battery system (200) is normally received from the primary CMU (100A).

Based on the cell status information for all battery modules in the battery system (200) not being normally received by the BMU (10) (“No” at step S55), at step S56, it may be displayed that cell monitoring in the battery system (200) is not possible, and various operations to transition the vehicle to a safe state may be performed.

Based on the cell status information for all battery modules in the battery system (200) being normally received by the BMU (10) (“Yes” in step S55), by performing the above-mentioned step S60, the BMU (10) may determine whether there is a status abnormality of the battery modules in the battery system (200) based on the real-time cell status information transmitted from the primary CMU (100A).

In this way, according to an embodiment of the present disclosure, by implementing the wireless interface units, i.e., the wireless IC managers #1, #2, in the primary CMU (100A) in a dual redundant configuration and performing operations to diagnose the wireless communication status for the wireless IC managers #1, #2 and reset them when necessary, when an abnormality occurs in one of the wireless IC managers #1, #2, the corresponding manager may be reset for normalization while normal wireless communication continues to be supported through the other manager. This approach may prevent complete failure of cell monitoring in the battery system (200) due to a single wireless IC failure in the primary CMU (100A).

Meanwhile, according to another embodiment of the present disclosure, one of the wireless IC managers #1, #2 in the primary CMU (100A) (e.g., the wireless IC manager #1) may receive the cell status information via wireless communication and transmit the cell status information to the BMU (10), but based on a reception error for the wireless IC manager #1 being diagnosed, may switch from the wireless IC manager #1 to the other wireless IC manager #2 to continue receiving the cell status information via wireless communication, and for the wireless IC manager #1, follow-up operations to resolve the reception error may be performed.

In the existing technology, as the BMU with the wireless manager role is placed at the front-most or rear-most location within the battery system, the wireless communication performance with CMUs with distant wireless communication paths may be degraded. In such case, there was a limitation in that cell monitoring for the battery module to which the corresponding CMU is connected may become impossible due to the BMU not being able to normally receive the cell status information measured and transmitted by the corresponding CMU.

According to various embodiments of the present disclosure as described above, by implementing the primary CMU at a location favorable for optimization of the structure/performance of wireless communication in the battery system, through securing freedom of positioning of the primary CMU, the overall performance of wireless communication in the battery system may be improved and the cell monitoring performance may be enhanced.

In the existing technology, a maintenance access panel had to be configured at the bottom of the battery system for BMU (with CPU) servicing, and consequently, there was an issue in that battery safety could not be secured in the event of a vehicle undercarriage collision because of potential damage to the watertight sealing.

According the various embodiments of the present disclosure as described above, by implementing a structure that performs BMS wireless communication using only CMUs through the implementation of the primary CMU in the battery system, the maintenance access panel for BMU servicing at the bottom of the battery system may also be removed due to the removal of the BMU from the battery system, thereby securing battery stability.

Further, in the existing technology, the operating voltage of the BMU in the battery system was the entire pack voltage, making it essential to secure electrical insulation and high voltage stability inside the battery system for the wiring and electrical connection parts.

In contrast, according to various embodiments of the present disclosure, by implementing a structure that performs BMS wireless communication using only CMUs through the implementation of the primary CMU in the battery system, greater flexibility in electrical insulation design and high-voltage safety measures considering the entire battery pack voltage may be secured due to the non-application of the BMU inside the battery system.

As used in the present disclosure (especially in the appended claims), the terms "a/an" and "the" include both singular and plural referents, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof ("for example", "such as") are merely to describe the present disclosure in greater detail. Therefore, it should be understood that the scope of the present disclosure is not limited to the example embodiments described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example embodiments described above, and rather intended to include the following appended claims, and all modifications, equivalents, and alternatives falling within the spirit and scope of the following claims.

1. A wireless battery management system comprising:
a plurality of cell monitoring unit (CMU)s connected to a plurality of battery module constituting a battery system, and configured to measure a status of each of the plurality of battery modules; and
a battery management unit (BMU) positioned externally to the battery system;
wherein a primary CMU among the plurality of CMUs having a wireless communication primary function is configured to receive, via wireless communication, cell status information measured by the plurality of CMUs, and to transmit the received cell status information to the BMU.

2. The wireless battery management system of claim 1, wherein the BMU is configured to receive cell status information for the plurality of battery modules within the battery system from the primary CMU, and to determine whether there is a status abnormality of the plurality of battery modules within the battery system.

3. The wireless battery management system of claim 1, wherein the primary CMU comprises two or more wireless interface units for wireless communication, and is configured to diagnose a wireless communication status for the two or more wireless interface units, to and reset one or more wireless interface units in which an error has been diagnosed.

4. The wireless battery management system of claim 1, wherein the BMU is positioned in an integrated power electronics module (IPEM).

5. The wireless battery management system of claim 3, wherein the BMU is configured to determine whether the cell status information for the plurality of battery modules within the battery system is normally received from the primary CMU.

6. The wireless battery management system of claim 5, wherein the primary CMU is configured to diagnose the wireless communication status when the cell status information for the plurality of battery modules is not normally received by the BMU.

7. The wireless battery management system of claim 6, wherein the primary CMU is configured to diagnose the wireless communication status by:
diagnosing the wireless communication status of the first wireless interface unit based on a wireless data packet success rate and a number of retransmissions received from the plurality of CMUs via a first wireless interface unit, among the two or more wireless interface units;
resetting the first wireless interface unit based on a reception error being diagnosed for the first wireless interface unit; and
resetting a second wireless interface unit, among the two or more wireless interface units, based on a reception error not being diagnosed for the first wireless interface unit.

8. The wireless battery management system of claim 3, wherein a communication structure between the BMU and the primary CMU is configured such that each wireless interface unit of the primary CMU is connected to the BMU via a wired communication.

9. The wireless battery management system of claim 1, wherein the primary CMU comprises:
a module measurement function unit configured to measure a status of a battery module to which the primary CMU is connected; and
a wireless communication primary function unit configured to receive, via wireless communication, cell status information measured by a plurality of CMUs other than the primary CMU among the plurality of CMUs, and by the module measurement function unit, and to transmit the received cell status information to the BMU.

10. The wireless battery management system of claim 1, wherein the wireless battery management system is positioned within a vehicle.

11. A cell monitoring unit (CMU), the CMU comprising:
a module measurement function unit configured to measure a status of a battery module to which the CMU is connected within a battery system; and
a wireless communication primary function unit configured to receive, via wireless communication, cell status information measured by a plurality of CMUs connected to other battery modules in the battery system and cell status information measured by the module measurement function unit, and to transmit the received cell status information to a battery management unit (BMU) positioned externally to the battery system.

12. The CMU of claim 11, wherein the wireless communication primary function unit comprises two or more wireless interface units for wireless communication, and is configured to diagnose a wireless communication status for the two or more wireless interface units, and to reset the one or more wireless interface units in which an error has been diagnosed.

13. The CMU of claim 11, wherein the wireless communication primary function unit is configured to use a power source different from a power source used by the module measurement function unit.

14. The CMU of claim 11, wherein the wireless communication primary function unit is configured to receive and use a vehicle power source different from a power source used by the module measurement function unit.

15. The CMU of claim 11, wherein the module measurement function unit is positioned in a first voltage domain having a higher voltage level than a predetermined value, and the wireless communication primary function unit is positioned in a second voltage domain having a lower voltage level than the predetermined value, and wherein the module measurement function unit in the first voltage domain and the wireless communication primary function unit in the second voltage domain are electrically isolated from one another within the CMU.

16. The CMU of claim 11, wherein the CMU is positioned within a vehicle.

17. An operation method for a wireless battery management system based on a cell monitoring unit (CMU), the method comprising:
measuring a status of the battery modules by a plurality of CMUs connected to a plurality of battery modules constituting a battery system;
receiving cell status information measured by the plurality of CMUs via wireless communication by a primary CMU having a wireless communication primary function among the plurality of CMUs; and
transmitting, by the primary CMU, the cell status information received via wireless communication to a battery management unit (BMU) implemented externally to the battery system.

18. The operation method of claim 17, further comprising:
determining, by the BMU, whether cell status information for the plurality of battery modules within the battery system is normally received from the primary CMU; and
based on the cell status information for the plurality of battery modules not being normally received by the BMU, diagnosing, by the primary CMU, a wireless communication status for two or more wireless interface units for wireless communication.

19. The operation method of claim 18, wherein the diagnosing a wireless communication status comprises:
diagnosing the wireless communication status of the first wireless interface unit based on a wireless data packet success rate and a number of retransmissions received from the plurality of CMUs via a first wireless interface unit among the two or more wireless interface units;
resetting the first wireless interface unit based on a reception error being diagnosed for the first wireless interface unit; and
resetting a second wireless interface unit among the two or more wireless interface units based on a reception error not being diagnosed for the first wireless interface unit.

20. The operation method of claim 18, wherein a communication structure positioned between the BMU and the primary CMU is configured such that each wireless interface unit of the primary CMU is connected to the BMU via a wired communication.
